(19) United States
(12) Patent Application Publication
(10) Pub. No.: US 2015/0087134 A1
(43) Pub. Date: Mar. 26, 2015

(54) SEMICONDUCTOR ISOLATION REGION UNIFORMITY

(71) Applicant: GLOBALFOUNDRIES Inc., Grand Cayman (KY)

(72) Inventors: Tsung-Liang CHEN, Cohoes, NY (US); Hsin-Neng TAI, Clifton Park, NY (US); Puneet KHANNA, Clifton Park, NY (US); Zhenyu HU, Clifton Park, NY (US); Huey-Ming WANG, Ballston Lake, NY (US)

(73) Assignee: GLOBALFOUNDRIES Inc., Grand Cayman (KY)

(21) Appl. No.: 14/032,978

(22) Filed: Sep. 20, 2013

(51) Int. Cl. H01L 21/762

(52) U.S. Cl. CPC H01L 21/76224
USPC 438/424

(57) ABSTRACT

Methods of facilitating isolation region uniformity include: patterning a semiconductor substrate to form at least one isolation opening within the semiconductor substrate, the patterning comprising leaving, at least in part, a protective hard mask above a portion of the semiconductor substrate; providing an insulating material within and over the at least one isolation opening, and planarizing the insulating material to facilitate fabricating an isolation region within the semiconductor substrate; stopping the planarizing on the protective hard mask and exposing at least a portion of the protective hard mask above the portion of the semiconductor substrate; and non-selectively removing a remaining portion of the insulating material over the at least one isolation opening and the exposed protective hard mask above the portion of the semiconductor substrate while leaving the insulating material within the at least one isolation opening and exposing upper surfaces of the semiconductor substrate, to facilitate isolation region uniformity.

### FIELD OF THE INVENTION

The present invention relates to semiconductor devices and methods of fabricating semiconductor devices, and more particularly, to methods of facilitating isolation region uniformity for use, for instance, in fabricating one or more semiconductor devices.

### BACKGROUND

A semiconductor device fabrication typically involves the process of fabricating isolation regions, including deep trench isolation regions and shallow trench isolation regions to electrically isolate various integrated circuits, within a single chip or wafer area. As the size of technology nodes continues to decrease, significant challenges continues to arise due to issues related to traditional semiconductor fabrication processing techniques, including issues related to lack of planarity or uniformity of isolation regions, between various integrated circuits.

### BRIEF SUMMARY

The shortcomings of the prior art are overcome and additional advantages are provided through the provision, in one aspect, of a method which includes, for instance: patterning a semiconductor substrate to form at least one isolation opening within the semiconductor substrate, the patterning including leaving, at least in part, a protective hard mask above a portion of the semiconductor substrate; providing an insulating material within and over the at least one isolation opening, and planarizing the insulating material to facilitate fabricating an isolation region within the semiconductor substrate; stopping the planarizing on the protective hard mask and exposing at least a portion of the protective hard mask above the portion of the semiconductor substrate; and non-selectively removing a remaining portion of the insulating material over the at least one isolation opening and the exposed protective hard mask above the portion of the semiconductor substrate while leaving the insulating material within the at least one isolation opening and exposing upper surfaces of the semiconductor substrate, to facilitate isolation region uniformity.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a cross-sectional elevational view of one embodiment of a conventional intermediate structure, including a semiconductor substrate and at least one isolation opening within the semiconductor substrate, obtained during an early stage of fabrication, in fabricating one or more conventional semiconductor devices;

FIG. 1B depicts the structure of FIG. 1A with an insulating material having been provided for use, for instance, in fabricating one or more conventional semiconductor devices;

FIG. 1C depicts the structure of FIG. 1B after planarization thereof;

FIG. 1D depicts the structure of FIG. 1C after removal of a portion of insulating material;

FIG. 1E depicts the structure of FIG. 1D with the protective hard masks having been removed;

FIG. 1F depicts the resultant structure of FIG. 1E after and additional planarization step;

FIG. 2A is a cross-sectional elevational view of one embodiment of an intermediate structure, including a semiconductor substrate, obtained during an early stage of fabrication, in accordance with one or more aspects of the present invention;

FIG. 2B depicts the structure of FIG. 2A, after patterning of the semiconductor substrate to define isolation openings, in accordance with one or more aspects of the present invention;

FIG. 2C depicts the structure of FIG. 2B, with an insulating material having been provided, in accordance with one or more aspects of the present invention;

FIG. 2D depicts the structure of FIG. 2C, after planarization thereof, in accordance with one or more aspects of the present invention; and

FIG. 2E depicts the structure of FIG. 2D, after non-selective removal of a remaining portion of the insulating material over the at least one isolation opening and exposed protective hard masks, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Further, note that in making reference below to the drawings (which are not drawn to scale for ease of understanding) the same reference numbers used throughout different figures designate the same or similar components.

In one aspect, semiconductor device fabrication, at an early stage of fabrication, typically involves the process of fabricating isolation regions to electrically isolate various integrated circuits, within a single chip or wafer area. By way of example, the isolation regions may include, for instance, shallow trench isolation (STI) region and deep trench isolation (DTI) region. For example, a shallow trench isolation (STI) region may typically include an isolation opening, that has been patterned or etched into the surface of the semiconductor substrate in the location, where the electrical isolation is desired. Subsequently, an insulating material such as silicon oxide may be provided within the isolation opening to create an electrical isolation between the desired integrated circuits. As the integration density of the semiconductor devices continues to increase, significant challenges continue to arise with traditional semiconductor fabrication processing techniques to electrically isolate various integrated circuits. For instance, a lack of planarity or uniformity of the isolation regions created using traditional semiconductor fabrication processes may be an issue in subsequent processing.

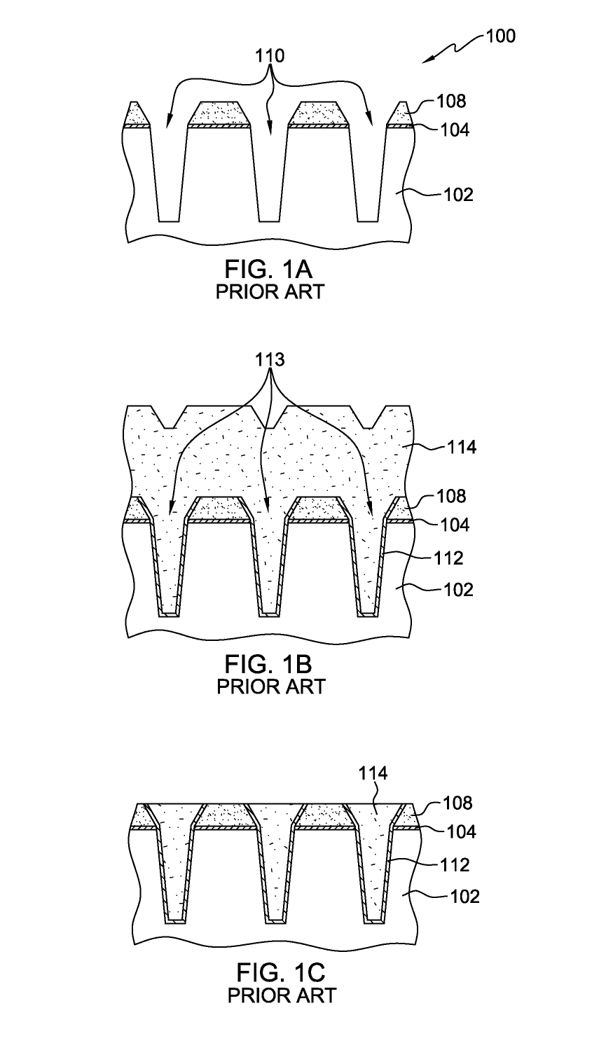

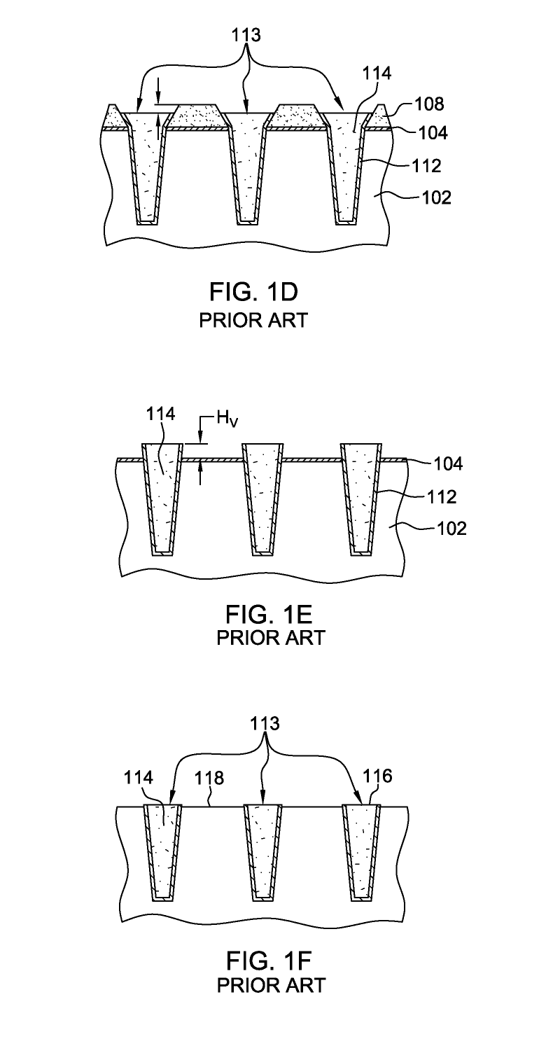

By way of example, FIGS. 1A-1E depict one embodiment of a conventional process for fabricating an isolation region for use, for instance, in semiconductor fabrication processing.

One embodiment of an intermediate process structure 100 is depicted in FIG. 1A. This structure 100 includes a semiconductor substrate 102, for instance, a silicon substrate. A thin oxide layer 104 (also referred to as pad oxide) may be disposed over semiconductor substrate 102, to protect the semiconductor substrate during subsequent processing. Thin oxide layer 104 may be grown, for example, by thermal oxidation and protective mask may be disposed over thin oxide layer 104. By way of example, although not depicted in figures, the protective mask may be a layer of silicon nitride, formed over thin oxide layer 104. The noted layers of structure 100 of FIG. 1A may be formed using a variety of different materials and fabrication techniques, such as chemical vapor deposition (CVD), atomic layer deposition (ALD), physical vapor deposition (PVD) or plasma-enhanced versions of such processes. The thickness of the depicted layers may also vary, depending on the particular application.

Continuing with FIG. 1A, one or more lithographic processing steps are performed to selectively pattern a portion of the protective mask along with a portion of thin oxide layer 104, to create laterally separated isolation openings 110 within semiconductor substrate 102. Although not depicted in figures, one skilled in art will know that, the lithographic processing steps may typically, include (for instance) providing an anti-reflective coating layer over the protective mask and providing a patterned photoresist layer over the anti-reflective layer. The patterning process may proceed through the layers to transfer the pattern from the patterned photoresist layer to etch through semiconductor substrate 102. These lithographic processing steps advantageously facilitate in creating one or more isolation openings 110 within semiconductor substrate 102 and leaving a protective hard mask 108 above a portion of semiconductor substrate 102. Any suitable conventional etching processes such as, reactive ion etching processes may be employed to anisotropically etch through semiconductor substrate 102 to create isolation opening 110.

As depicted in FIG. 1B, isolation opening 110 of FIG. 1A may be lined with a conformally deposited isolation liner 112. Isolation liner 112 may be, for example, a thin layer of silicon dioxide grown by thermal oxidation within isolation opening 110 and extending along the sidewalls of protective hard mask 108. An insulating material 114 is then provided (for instance, over isolation liners 112) within and over the isolation openings, resulting in laterally-separated, electrically isolated isolation regions 113 within the semiconductor substrate 102. This insulating material 114 may be deposited using a variety of techniques, such as, for example, chemical vapor deposition (CVD), plasma-enhanced CVD, or sub-atmospheric pressure thermal CVD (SACVD) processes and the thickness of the layer above protective hard mask 108, may be (in one example) sufficient to allow for subsequent planarization of the structure. By way of example, insulating material 114 may be fabricated of or include an oxide material. For instance, high-density plasma (HDP) oxide, high aspect ratio process (HARP) oxide or tetraethyl orthosilicate (TEOS) based silicon dioxide may be deposited as insulating material 114 within the laterally separated isolation opening, using plasma-enhanced CVD process.

As illustrated in FIG. 1C, a chemical-mechanical polish or an etch-back polish is then employed to polish away excess insulating material 114, using (in one embodiment) the protective hard masks above the upper surfaces of semiconductor substrate 102, as an etch stop, thereby exposing protective hard masks 108.

A portion of insulating material 114 is then removed from the upper surfaces of electrically-isolated isolation regions 113, as depicted in FIG. 1D. This removal process may be performed by employing a deglazing etching process using, for instance, a deglaze etchant that is highly selective to an oxide etching process. In one example, the etchant may be dilute hydrofluoric acid with a dilution of about 1:1000 to about 1:500. The deglazing etching process may be performed to remove any residual oxide from above the upper surfaces of protective hard mask 108, as well as recessing insulating material 114 along with isolation liner 112 from above the upper surfaces of isolation region 113, and to expose the protective hard mask for a subsequent removal process. This deglazing etching process performed to etch away any residual layers is, disadvantageously, not a complete etch process, resulting only in partial removal of the insulating material, while leaving a portion of insulating material 114 above the upper surfaces of isolation region 113, and thereby creating a height variation between the upper surfaces of protective hard masks 108 and the upper surfaces of insulating material 114, which would affect any subsequent removal process.

As depicted in FIG. 1E, the exposed protective hard mask 108 is next selectively removed, from (for instance, from above thin oxide layer 104) the upper surfaces of semiconductor substrate 102, by a selective etch process. By way of an example, the exposed protective hard mask 108 may be selectively removed using hot phosphoric acid. The undesirable height variations caused by above described deglazing process, are translated to height variations between the upper surfaces of insulating material 114 and upper surfaces of thin oxide layer 104, during this selective removal process. In a specific example, the height variation (Hᵥ) between the partially recessed insulating material 114 and thin oxide layer 104 results in non-planarity or uniformity of the upper surfaces in the semiconductor structure, for a subsequent fabrication processing.

As illustrated in FIG. 1F, an additional chemical-mechanical polishing is then performed to remove remaining insulating material 114 from above isolation region 113 along with thin oxide layer 104 (see FIG. 1E). This additional chemical-mechanical polishing is performed to result in the upper surfaces 116 of insulating material 114 within isolation opening 110 (FIG. 1A) to be coplanar with the upper surfaces 118 of semiconductor substrate 102. However, the height variation (Hᵥ (see FIG. 1E)) between the thin oxide layer and the partially recessed insulating material disadvantageously results in a lack of planarity or uniformity of the resultant semiconductor structure. This lack of planarity or uniformity result undesirable thickness variations across the semiconductor wafer, during subsequent fabrication processing.

As explained further below, the methods disclosed herein in accordance with aspects of the invention, address these challenges in semiconductor fabrication processing, and thereby enhance the use of isolation regions in advanced technology nodes. Moreover, in accordance with aspects of the present invention, conventional processing steps, as described above, including planarization steps, deglaze and selective remove of protective hard masks, such as nitride hard masks are eliminated, while providing surprisingly superior isolation region uniformity results.

Generally stated, disclosed herein, in one aspect, is a method which includes: patterning a semiconductor substrate to form at least one isolation opening within the semiconductor substrate, the patterning including leaving, at least in part, a protective hard mask above a portion of the semiconductor substrate, providing an insulating material within and over the at least one isolation opening, and planarizing the insulating material to facilitate fabricating an isolation region within the semiconductor substrate, stopping the planarizing on the protective hard mask and exposing at least a portion of the protective hard mask above the portion of the semiconductor substrate, and non-selectively removing a portion of the insulating material over the at least one isolation opening and the exposed protective hard mask above the portion of the semiconductor substrate while leaving the insulating material within the at least one isolation opening and exposing upper surfaces of the semiconductor substrate, to facilitate isolation region uniformity.

In one example, patterning the semiconductor substrate includes selectively etching through a portion of a protective mask and a portion of the semiconductor substrate to create at least one isolation opening within the semiconductor substrate, while leaving, at least in part, the protective hard mask above a portion of the semiconductor substrate. The semiconductor substrate includes a protective mask disposed over the semiconductor substrate, where the protective mask may be fabricated of or includes a nitride material. In one example, the leaving includes leaving protective hard mask, above a portion of the semiconductor substrate having a thickness of about 30 nanometers to about 60 nanometers and where the protective hard mask may include, for example, a nitride material.

In one embodiment, the providing the insulating material includes providing the insulating material within and substantially over the at least one isolation opening, planarizing an exposed surface of the insulating material to be substantially coplanar with a surface of the exposed portion of the protective hard mask above the portion of the semiconductor substrate, and where the insulating material includes an oxide material. The planarizing further includes planarizing the exposed surface of the insulating material, and leaving, at least in part, a portion of the insulating material over the at least one isolation opening. In one example, the leaving includes leaving the portion of the insulating material over the at least one isolation opening having a thickness of about 200 nanometers to about 300 nanometers.

In enhanced processing, the non-selectively removing includes non-selectively etching or non-selectively planarizing the remaining portion of the insulating material over the at least one isolation opening and the exposed protective hard mask above the portion of the semiconductor substrate, where during the non-selectively removing includes, upper surface of the insulating material within the at least one isolation opening being coplanar with the exposed upper surfaces of the semiconductor substrate. The non-selectively removing further includes, in one example, employing processes that are non-selective to an oxide or nitride etching processes.

In one aspect, the non-selectively etching includes non-selectively etching the remaining portion of the insulating material over the at least one isolation opening along with the exposed protective hard mask above the portion of the semiconductor substrate using reactive ion etching or plasma-etching, where during the non-selectively etching includes, upper surface of the insulating material within the at least one isolation opening being coplanar with exposed upper surfaces of the semiconductor substrate.

In another aspect, the non-selectively planarizing includes non-selectively planarizing the remaining portion of the insulating material over the at least one isolation opening along with the exposed protective hard mask above the portion of the semiconductor substrate, where during the non-selectively planarizing includes, upper surface of the insulating material within the at least one isolation opening being coplanar with exposed upper surfaces of the semiconductor substrate.

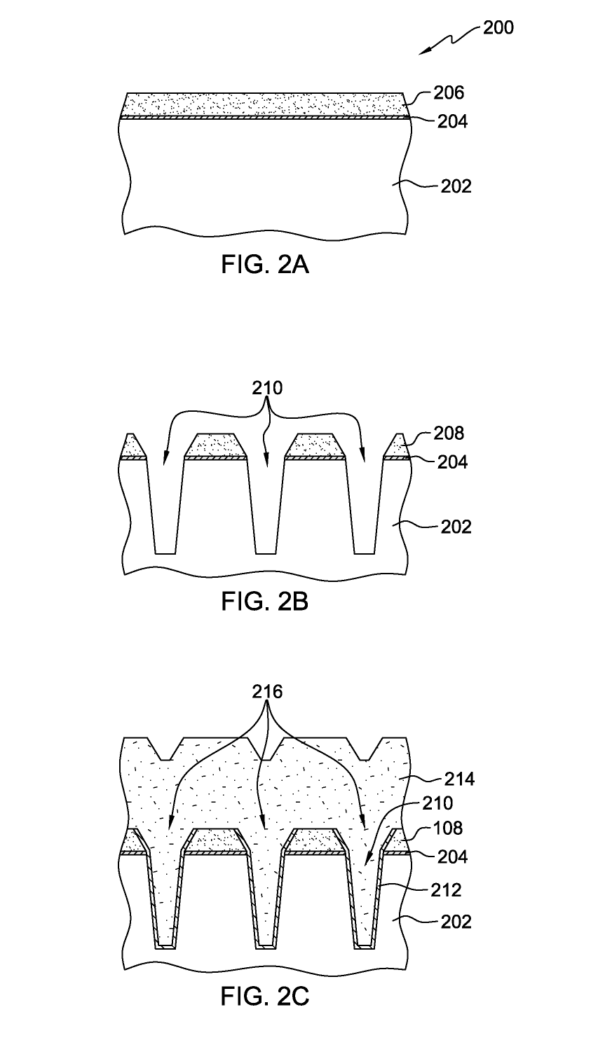

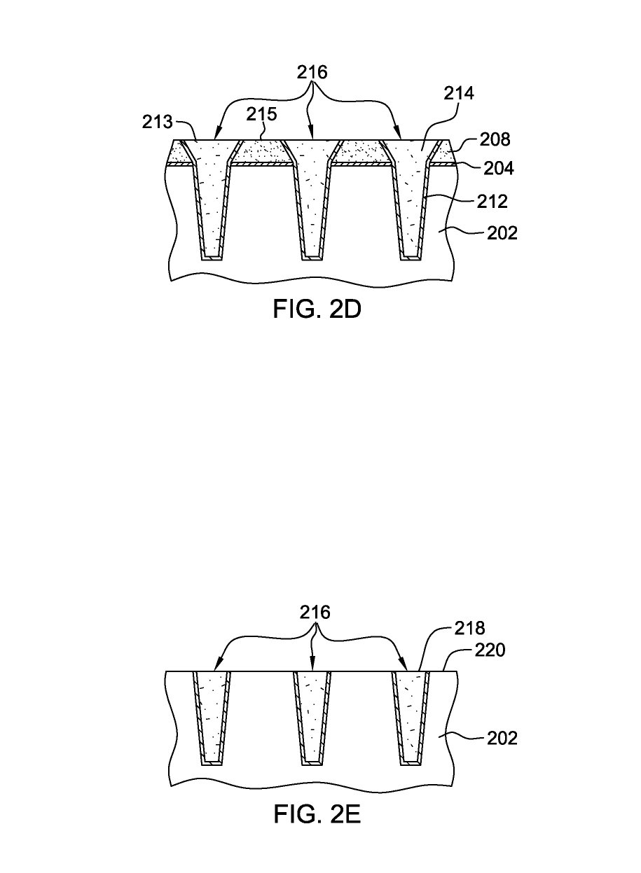

FIG. 2A illustrates an intermediate structure 200, attained during an early stage of semiconductor fabrication processing, in accordance with one or more aspects of the present invention. At the point of fabrication, depicted in FIG. 1, intermediate structure 200 includes a semiconductor substrate 202, such as a bulk semiconductor material, for example, a bulk silicon wafer. In one example, semiconductor substrate 202 may include any silicon-containing substrate including, but not limited to, silicon (Si), single crystal silicon, polycrystalline Si, amorphous Si, silicon-on-nothing (SON), silicon-on-insulator (SOI), or silicon-on-replacement (SRI) substrates and the like. Semiconductor substrate 202 may in addition or instead include various isolations, dopings, and/or device features. The semiconductor substrate may include other suitable elementary semiconductors, such as, for example, germanium (Ge) in crystal, a compound semiconductor such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

A thin oxide layer 204 (also referred to as pad oxide) may be disposed over semiconductor substrate 202, to protect the semiconductor substrate during subsequent processing. In one example, thin oxide layer 204 may be grown by thermal oxidation. The noted layers of structure 200 of FIG. 2A may be formed using a variety of different materials and fabrication techniques, such as chemical vapor deposition (CVD), atomic layer deposition (ALD), physical vapor deposition (PVD) or plasma-enhanced versions of such processes. The thickness of the depicted layers may also vary, depending on the particular application.

A protective mask 206 may be disposed over thin oxide layer 204, that is provided, for instance, over semiconductor substrate 202. By way of example only, the protective mask may be deposited using conventional deposition processes, such as, for example, chemical vapor deposition (CVD), low-pressure CVD, or plasma-enhanced CVD (PE-CVD). In one example, protective mask 206 may include or be fabricated of a material such as, for example, silicon nitride. In a specific example, silicon nitride may be deposited using process gases such as, for example, dichlorosilane (SiH₂Cl₂) and ammonia (NH₃) and using known process conditions. In another example, silicon nitride may also or alternatively be deposited using halogen-free precursor such as, for example, bis(t-butylamino)silane (BTBAS) (SiC₈N₂H₂₂) and ammonia (NH₃) at about 550° C.

As depicted in FIG. 2B, and as described previously herein, one or more lithographic processing steps may performed to selectively pattern a portion of protective mask 206 (see FIG. 2A) along with a portion of thin oxide layer 204, to create laterally separated isolation openings 210 within semiconductor substrate 202. Although not depicted in figures, one skilled in art will know that, the lithographic processing steps may typically, include (for instance) providing an anti-reflective coating layer over the protective mask and providing a patterned photoresist layer over the anti-reflective layer. The patterning process may proceed through the layers to transfer the pattern from the patterned photoresist layer to etch through semiconductor substrate 202. These lithographic processing steps advantageously facilitate in creating one or more isolation openings 210 within semiconductor substrate 202 and leaving a protective hard mask 208 above a portion of semiconductor substrate 202. In one example, protective hard mask 208 may include or be fabricated of a nitride material, such as, for instance, silicon nitride, and the thickness of the protective hard mask above (for instance, over thin oxide layer 204) above a portion of semiconductor substrate 202 may be in the range of about 30 nanometers to about 60 nanometers. Any suitable conventional anisotropic dry etching processes such as, reactive ion etching processes may be employed to anisotropically etch through semiconductor substrate 202 to create isolation opening 210. In a specific example, the reactive ion etching may be performed using fluorine based chemistry and involving gases such as tetrafluoromethane (CF₄), trifluoromethane (CHF₃), difluoromethane (CH₂F₂), fluoromethane (CH₃F), octofluoromethane (C₄F₈), hexafluoro-1,3-butadiene (C₄F₆), sulfur hexafluoride (SF₆) and oxygen (O₂)

As depicted in FIG. 2C, isolation opening 210 may be lined with a conformally deposited isolation liner 212. As used herein “isolation liner” refers generally to any film or layer which may form part of the resultant isolation region, and may be, for example, a thin layer of silicon dioxide grown by thermal oxidation within isolation opening 210 and extending along the sidewalls of protective hard mask 208. An insulating material 214 may be provided (for instance, over isolation liner 212) within and substantially over laterally separated isolation openings 210, resulting in laterally-separated, electrically-isolated isolation region 216 within semiconductor substrate 202. This insulating material 214 may be deposited using a variety of techniques, such as, for example, chemical vapor deposition (CVD), plasma-enhanced CVD, or sub-atmospheric pressure thermal CVD (SACVD) processes and the thickness of the layer above protective hard mask 208, may be (in one example) sufficient to allow for subsequent planarization of the structure. By way of example, insulating material 214 may be fabricated of or include an oxide material. For instance, high-density plasma (HDP) oxide, high aspect ratio process (HARP) oxide or tetraethyl orthosilicate (TEOS) based silicon dioxide may be deposited as insulating material 214 within and substantially over laterally separated isolation opening 210, using plasma-enhanced CVD process. In a specific example, the chemical vapor deposition process may be employed using tetraethyl orthosilicate (TEOS) and ozone (O₃) as reactants to deposit the tetraethyl orthosilicate based silicon dioxide within and substantially over isolation opening 210.

As illustrated in FIG. 2D, a non-selective chemical-mechanical polish or an etch-back polish may then be employed to polish away excess insulating material 214 and excess isolation liner 212 with the chemical-mechanical polishing terminating at, for instance, protective hard masks 208, exposing the protective hard mask and resulting in the height of laterally-separated, electrically-isolated isolation region 216 being substantially equal to the height of exposed protective hard masks 208 as illustrated. As discussed above, the laterally-separated, electrically-isolated isolation region 216 is being filled with insulating material 214. The result is that the exposed surface 213 of insulating material 214 over isolation opening 210 may be substantially coplanar with a surface 215 of the exposed portion of protective hard mask 208. In a specific example, the thickness of the insulating material over isolation opening 210 may be about 200 nanometers to about 300 nanometers.

As depicted in FIG. 2E, a non-selective removal process may then be employed to remove remaining portion of excess insulating material 214 over the laterally-separated, electrically-isolated isolation region 216 and the exposed protective hard masks 208. This non-selective removal process may include employing processes, for instance, a non-selective planarization process or non-selective etching process, that are non-selective to an oxide etching process or a nitride etching process. As understood, non-selective in this context means that the polish rate or etch rate is close between insulating material 214 and protective hard mask 208 (see FIG. 2D), which in one example, are an oxide and a nitride, respectively. The result is that the upper, exposed surfaces 218 of insulating material 214 within the laterally-separated, electrically-isolated isolation region 216 and the upper surfaces 220 of semiconductor substrate 202, are substantially coplanar. Note that the non-selective chemical-mechanical polish or non-selective etching process performed advantageously result in non-selective removal of thin oxide layer 204 (see FIG. 2D) over the upper surface of the semiconductor substrate along with a non-selective removal of isolation liner 212 (see FIG. 2D) along the sidewalls of exposed protective hard mask 208. In one example, non-selective planarizing process, for instance, a non-selective chemical-mechanical polishing may be performed to remove the remaining portion of excess insulating material 214 over isolation opening 210 (see FIG. 2C) and the exposed protective hard masks 208. By way of specific example, a Fujimi-slurry may be employed to perform a CMP polish back of the excess insulating material and the exposed protective hard masks. In another example, a non-selective etching process, such as, for instance, planar reactive ion etching or plasma etching process may be performed to remove the excess insulating material and the exposed protective hard masks.

Advantageously, the non-selective removal process, for instance, planar reactive ion etching process or a non-selective chemical-mechanical polishing, results in eliminating cost-prohibitive conventional process steps such as, for example, deglazing etching process, and additional planarizing steps. This non-selective removal process also advantageously results in facilitating the isolation region uniformity by eliminating the height variation between the upper surfaces of the insulating material within the isolation region and the exposed upper surfaces of the semiconductor substrate, and thereby improving the performance of the resultant semiconductor structure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
patterning a semiconductor substrate to form at least one isolation opening within the semiconductor substrate, the patterning comprising leaving, at least in part, a protective hard mask above a portion of the semiconductor substrate;
providing an insulating material within and over the at least one isolation opening, and planarizing the insulating material to facilitate fabricating an isolation region within the semiconductor substrate;
stopping the planarizing on the protective hard mask and exposing at least a portion of the protective hard mask above the portion of the semiconductor substrate; and
non-selectively removing a remaining portion of the insulating material over the at least one isolation opening and the exposed protective hard mask above the portion of the semiconductor substrate while leaving the insulating material within the at least one isolation opening and exposing upper surfaces of the semiconductor substrate, to facilitate isolation region uniformity.

2. The method of claim 1, wherein the non-selectively removing comprises non-selectively etching or non-selectively planarizing the remaining portion of the insulating material over the at least one isolation opening and the exposed protective hard mask above the portion of the semiconductor substrate, and wherein during the non-selectively removing, upper surface of the insulating material within the at least one isolation opening is coplanar with the exposed upper surfaces of the semiconductor substrate.

3. The method of claim 2, wherein the non-selectively removing further comprises employing processes that are non-selective to oxide and nitride etching processes.

4. The method of claim 2, wherein the non-selectively etching comprises non-selectively etching the remaining portion of the insulating material over the at least one isolation opening along with the exposed protective hard mask above the portion of the semiconductor substrate using reactive ion etching or plasma etching, wherein during the non-selectively etching, upper surface of the insulating material within the at least one isolation opening is coplanar with exposed upper surfaces of the semiconductor substrate.

5. The method of claim 2, wherein the non-selectively planarizing, comprises non-selectively planarizing the remaining portion of the insulating material over the at least one isolation opening along with the exposed protective hard mask above the portion of the semiconductor substrate, wherein during the non-selectively planarizing, upper surface of the insulating material within the at least one isolation opening is coplanar with exposed upper surfaces of the semiconductor substrate.

6. The method of claim 5, wherein the planarizing of the insulating material comprises planarizing an exposed surface of the insulating material to be substantially coplanar with a surface of the exposed portion of protective hard mask above the portion of the semiconductor substrate.

7. The method of claim 1, wherein the patterning the semiconductor substrate comprises selectively etching through a portion of a protective mask and a portion of the semiconductor substrate to create at least one isolation opening within the semiconductor substrate, while leaving, at least in part, the protective hard mask above a portion of the substrate.

8. The method of claim 7, wherein the semiconductor substrate comprises a protective mask disposed over the semiconductor substrate, and wherein the protective mask comprises a nitride material.

9. The method of claim 7, wherein the leaving comprises leaving protective hard mask above a portion of the semiconductor substrate comprising a thickness of about 30 nanometers to about 60 nanometers and wherein the protective hard mask comprises a nitride material.

10. The method of claim 1, wherein the providing the insulating material comprises providing the insulating material within and substantially over the at least one isolation opening, planarizing an exposed surface of the insulating material to be substantially coplanar with a surface of the exposed portion of the protective hard mask above the portion of the semiconductor substrate, and wherein the insulating material comprises an oxide material.

11. The method of claim 10, wherein the planarizing further comprises planarizing the exposed surface of the insulating material, and leaving, at least in part, a portion of the insulating material over the at least one isolation opening.

12. (canceled)

13. The method of claim 1, wherein the non-selectively removing comprises non-selectively etching or non-selectively planarizing the remaining portion of the insulating material over the at least one isolation opening and the exposed protective hard mask above the portion of the semiconductor substrate, using processes that are non-selective to an oxide and nitride etching processes.

14. The method of claim 13, wherein the non-selectively etching comprises non-selectively etching the remaining portion of the insulating material over the at least one isolation opening along with the exposed protective hard mask above the portion of the semiconductor substrate using reactive ion etching or plasma etching, wherein during the non-selectively etching, upper surface of the insulating material within the at least one isolation opening is coplanar with exposed upper surfaces of the semiconductor substrate.

15. The method of claim 13, wherein the non-selectively planarizing comprises non-selectively planarizing the remaining portion of the insulating material over the at least one isolation opening along with the exposed protective hard mask above the portion of the semiconductor substrate, wherein during the non-selectively planarizing, upper surface of the insulating material within the at least one isolation opening is coplanar with exposed upper surfaces of the semiconductor substrate.

16. The method of claim 1, wherein the protective hard mask comprises a nitride material and the insulating material comprises an oxide material.

17. The method of claim 1, wherein the patterning is performed so that the protective hard mask is absent from the at least one isolation opening.

18. The method of claim 1, further comprising disposing art isolation liner conformally within the at least one isolation opening and extending over the semiconductor substrate, the isolation liner being adjacent to the insulating material and the semiconductor substrate within the at least one opening.

19. The method of claim 18, wherein the non-selectively removing comprises non-selectively removing the remaining portion of the insulating material over the at least one isolation opening along with a remaining portion of the isolation liner and the protective hard-mask above the portion of the semiconductor substrate.

20. The method of claim 1, further comprising disposing an oxide layer conformally within the at least one isolation opening and extending over the semiconductor substrate, the oxide layer being adjacent to the insulating material and the semiconductor substrate within the at least one opening, and wherein the patterning is performed so that the protective hard mask is absent from the at least one isolation opening.

21. The method of claim 1, further comprising depositing an oxide layer adjoining the protective hard-mask and the semiconductor substrate, and the method further comprising disposing an isolation liner conformally within the at least one isolation opening and providing the insulating material conformally over the isolation liner, and wherein the non-selectively removing comprises non-selectively removing the oxide layer, the protective hard-mask, the isolation liner along with the remaining portion of the insulating material, while leaving the insulating material within the at least one isolation opening and exposing upper surfaces of the semiconductor substrate, the non-selectively removing being performed so that an upper surface of the insulating material within the at least one isolation opening is coplanar with the exposed upper surface of the semiconductor substrate.
